(19) United States
(12) Patent Application Publication
(10) Pub. No.: US 2004/0009417 A1
(43) Pub. Date: Jan. 15, 2004

(54) Method for making fine prints from oscillations in fresnel diffraction patterns in ultra high resolution lithography

(76) Inventor: Antony J. Bourdillon, San Jose, CA (US)

Correspondence Address: Antony J Bourdillon, P.O. Box 700001, San Jose, CA, 95170-0001, US

(21) Appl. No.: 10/418,680

(22) Filed: Apr. 21, 2003

Related U.S. Application Data
(60) Provisional application No. 60/395,298, filed on Jul. 12, 2002.

(51) Int. Cl. G03F 7/20; G03F 7/26; G21K 5/00; G03F 1/00

(52) U.S. Cl. 430/30; 430/311; 378/34; 430/296; 430/5

(57) ABSTRACT

This method of Fresnel oscillations takes advantage of oscillation effects within Fresnel patterns to produce finer resolution than can be printed in the prior art. Selected patterns are printed by selecting the mask-wafer gap for a given wavelength, or range of wavelengths, and given mask feature size. Following the principles of the coherence and with an optimization of bandwidth, the method of Fresnel oscillations employs paradigms or simulations in mask shapes to print specified patterns. By these methods, exposure times and throughput are optimized, consistent with required resolution in printing. Mask-wafer gaps and clear mask feature sizes are kept large. With multiple exposures, fine oscillation patterns in two dimensions can be printed with demagnification factors down to 20X the size of clear mask features.

### CROSS-REFERENCE TO RELATED APPLICATIONS

The invention uses the transmission of previous patent No. 6,383,697, Ultra high resolution lithographic imaging and printing and defect reduction by exposure near the critical condition using Fresnel diffraction.,

and of co-pending application, Ser. No. 10/041304, Mask shaping using temporal and spatial coherence in ultra high resolution lithography.

This application is entitled to the benefit of Provisional Patent Application Ser# 60/395298 filed Jul. 12, 2002.

### BACKGROUND

1. Field of Invention

This invention applies to the field of micro-lithography and the application of microlithography as a tool in development and production of micro-electronic devices, integrated circuits, and micro-machines.

2. Discussion of Prior Art

In Ultra High Resolution Lithography (UHRL, U.S. Pat. No. 6,383,697), printing is achieved by demagnifying clear mask features without the use of either lenses or mirrors between the mask and a resist coated wafer. The mask is placed in proximity to the wafer, separated by a precise gap. The demagnification of the mask features results from the deliberate use of two-sided bias in UHRL. Typically, X-rays are used for exposing resists spun onto a wafer and placed near a Critical Condition (CC) with respect to the mask. Prints with dimensions about 25 nanometers have been demonstrated.

In UHRL, as in next generation lithography, the classical concept of fidelity in the reproduction of masks was relaxed. The use of masks with comparatively large clear features, employed with comparatively large mask-wafer gaps, provided an unexpected extension to Proximity X-ray Lithography (PXL) which had previously presupposed classical fidelity in the reproduction of masks, including 1X printing (i.e. not demagnified). In UHRL, by contrast to prior 1X PXL, the masks produce special effects which were corrected by a second invention namely, mask shaping using temporal and spatial coherence (MASC).

Among next generation lithographies competing for sub-100 nm patterning, PXL is the most advanced and mature, so that extensibility, through UHRL, is of special significance. The technique can be used as much for the printing of modem semiconductor integrated circuits as for fabricating micromachines and micro electro-mechanical systems. The fact that high precision lenses or high precision mirrors are not needed and that the light source is typically bright, with high throughput, provides technical and economic advantages, across the industry, for sub-100 nm patterning with UHRL.

In MASC, the purpose was to minimize interference effects within the printed image and to print ideal shapes with uniform intensity in the aerial images. This minimization of interference limited the demagnification of features. The consequent limitation in demagnification resulted in limitations in the size of mask-wafer gaps. Such gaps are a critical experimental parameter in the printing of fine features.

The limitation in demagnification had the second consequence that, for given print feature sizes, clear mask features had to be unnecessarily small, and this is a second critical parameter in the printing of fine features.

In UHRL and MASC one feature was printed from each clear mask feature exposed.

### SUMMARY OF THE INVENTION

The further reduction in print feature size is made using oscillations within the Fresnel diffraction pattern. I call them Fresnel oscillations. The further reduction is due to fundamental differences in the selection of exposure and development conditions. UHRL and MASC both presupposed two-sided bias as the means for demagnifying clear mask features; whereas in the printing of Fresnel oscillations, the bias is at least three sided, including two side biases plus one or more internal biases. I call this multiple bias. In UHRL and MASC, each clear mask feature is used to print only one feature per exposure; whereas in the printing of Fresnel oscillations, two or more features are typically printed.

In my method, the oscillations within Fresnel patterns are used to produce finer resolution than can be printed in UHRL or MASC. Selected patterns are printed by selecting the mask-wafer gap for a given wavelength, or range of wavelengths, and given mask feature size. Following the principles of the coherence and with an optimization of bandwidth, the method employs paradigms or simulations in mask shapes to print specified patterns. By these methods, exposure times and throughput are optimized, consistent with required resolution in printing. Mask feature sizes are further increased, compared with UHRL, due to higher demagnification factors, and mask-wafer gaps are correspondingly increased. With multiple exposures, fine oscillation patterns in two dimensions can be printed.

Whereas Fresnel oscillations were previously smeared in MASC, I here apply the opposite intention which is to print fine sub-patterns produced by the oscillations within the aerial image. By this means, finer patterns can be printed than in the above cited inventions, while retaining the general advantages of UHRL. Typically, a mask-wafer gap that is shorter than for the Critical Condition is used. Typically, higher temporal and spatial coherence are used than in UHRL and MASC.

Prints with a high demagnification of down to about 20X can be made with good contrast. The resolution can be extended to higher demagnification factors with less contrast. The resolution is higher than is attainable with either UHRL or MASC, typically 3X.

The method is described firstly, for simplicity, for one-dimensional imaging through slits but the method applies equally to two-dimensional imaging. The method takes advantage of the modern control of resist processing.

### OBJECTS OF THE INVENTION

The limitations of UHRL are overcome by application of the opposite intention to that described in MASC. I select exposure conditions and development level so as to print fine sub-patterns produced by Fresnel oscillations within the aerial image of a clear mask feature. In consequence, larger demagnification factors can be employed, down to 20X. Since the mask to wafer gap depends on the square of the demagnification factor, the gap can be significantly enlarged. This enlargement of gap is a significant experimental feature.

Moreover the fabrication of masks is simplified because the clear mask features are also significantly enlarged owing to larger selected demagnification factor. Whereas, in the prior art, only one mask feature was printed from each clear mask feature; my method of Fresnel oscillations employs multiple prints with value for increased printing speed and wafer throughput.

More generally, by using oscillations in Fresnel diffraction, finer patterns can be printed, than in UHRL and MASC, while retaining the general advantages of UHRL.

The method is described firstly, for simplicity, for one-dimensional imaging through slits but the method applies also to two-dimensional imaging, whether with single exposures or with multiple exposures.

It is an object of the invention to reduce the feature sizes in Ultra High Resolution Lithography by exposing resist at set distances from the mask and to selectively develop oscillation patterns that occur at the resist within the Fresnel pattern of a clear mask feature.

It is a second object of the invention to print comparatively small features with comparatively large mask-wafer gaps.

It is a third object of the invention to expose resists using aerial images of good contrast.

It is a fourth object of the invention to control, by temporal and spatial coherence, the resolution of selected image features when using the oscillations within the Fresnel patterns.

It is a fifth object of the invention to apply temporal coherence by the selection of band width in incident radiation, so as to optimize the selected oscillation features for printing. The selection of band width is done by various conventional means including the use of filters, of reflecting mirrors at required angles of incidence, and of operating parameters of the radiation source.

It is a sixth object of the invention to optimize throughput by selecting band width, consistent with high incident flux and resolution, due to temporal and spatial coherence when using the oscillations within the Fresnel patterns.

It is a seventh object of the invention to apply principles of temporal and spatial coherence to optimize, through simulation, the mask shapes suited to the printing of two-dimensional patterns when using the oscillations within the Fresnel patterns. The mask fabrication methods are otherwise conventional.

It is an eighth object of the invention to print multiple features from a single exposure of each clear mask feature

It is a ninth object of the invention to print more complex oscillation patterns by the superposition of multiple exposures.

It is a tenth object of the invention to provide a method for comparing various features, including mask-wafer gap, resolution, and mask feature size, in an “Oscillation Condition” so that the process can be optimized.

It is an eleventh object of the invention to optimize contrast in proximity lithography by selecting development levels where the said contrast in the aerial image is high.

It is a twelfth object of the invention to fabricate electronic, mechanical, magnetic or any other devices by the processes described in the above objectives.

### DRAWING FIGURES

The present invention will become more fully understood from the detailed description given hereinbelow and the accompanying drawings which are given by way of illustration only, and thus are not limitative of the present invention, and wherein:

FIG. 1 is a schematic exposure system according to the invention

FIG. 2 is a simulation of Fresnel diffracted current transmitted by a clear mask feature.

FIG. 3 is the well known Cornu spiral that is and adapted in the invention

FIG. 4 simulates aerial images at the exposure condition having dimensionless slit width, Δν=3.8

FIG. 5 represents simulated aerial images the with Δν=1.4

FIG. 6 represents simulated aerial images near the critical condition, Δν=2.4

FIG. 7 shows a schematic example of a method for making a fine two-dimensional pattern by multiple exposure.

FIG. 8 is a high level flow chart showing the inventive procedure.

### Reference Numerals in Drawings

10. X-rays

11. Mask

12. Resist coated onto wafer

14. Wave front

15. Lag

17. Axial amplitude at an Oscillation Condition

18. Axial amplitude at the Critical Condition

19. Axial amplitude for 1X

20. Dimensionless slit width at the OC with Δν=3.8

21. Internal bias

22. One sided bias

23. One sided bias

24. Dimensionless slit width with Δν=1.4 for 1X printing

25. Dimensionless slit width at CC with Δν=2.4

26. One sided bias

30. Clear mask feature

31. Dose above development level set as in 20 and 22

32. Clear mask feature rotated

33. Corresponding dose

34. Print at double development level set in 31 and 33

### DETAILED DESCRIPTION OF INVENTION

Main embodiment

Ultra High Resolution Lithography (UHRL) definition:

UHRL was performed by proximity printing (without lenses or mirrors between mask and wafer) from masks placed near a “Critical Condition” (defined below). The technique made positive use of Fresnel diffraction and relaxed the classical requirements for fidelity in the reproduction from masks. In consequence the prior requirement for 1X printing in proximity was also relaxed. UHRL capitalized on the enhancement of resolution that resulted from the deliberate application of two sided bias in lithographic imaging and printing. By preference, printing occurred when optimized at or near the “Critical Condition”. The resist processing was systematically controlled. Demagnification of clear mask features occurred by two-sided bias. The optical field was not demagnified but was kept compact as in IX PXL. The term “bias” or “two sided bias” was defined as the difference between mask feature size, W, and printed feature size, ω, i.e. the pattern width at the selected development level. More formally bias was defined as, b=W−ω. In my method using Fresnel oscillations, the “bias” is more than two sided and includes internal bias. Typically, more than one feature is printed from each clear mask feature.

The technique is used, typically, as a next generation lithography and has many consequences including fine resolution, large mask features, fast exposure times, large mask to wafer gaps, and avoidance of sidebands.

Critical Condition (CC) definition:

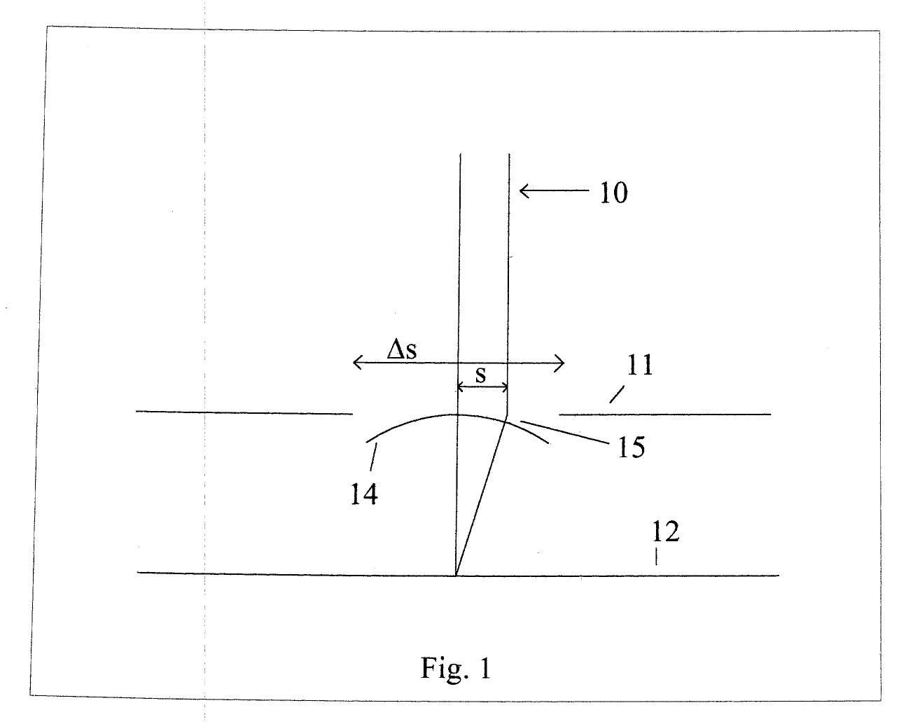

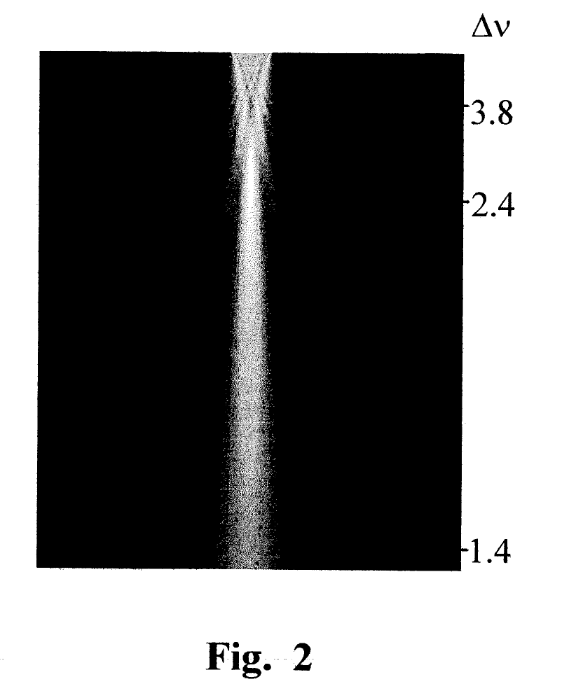

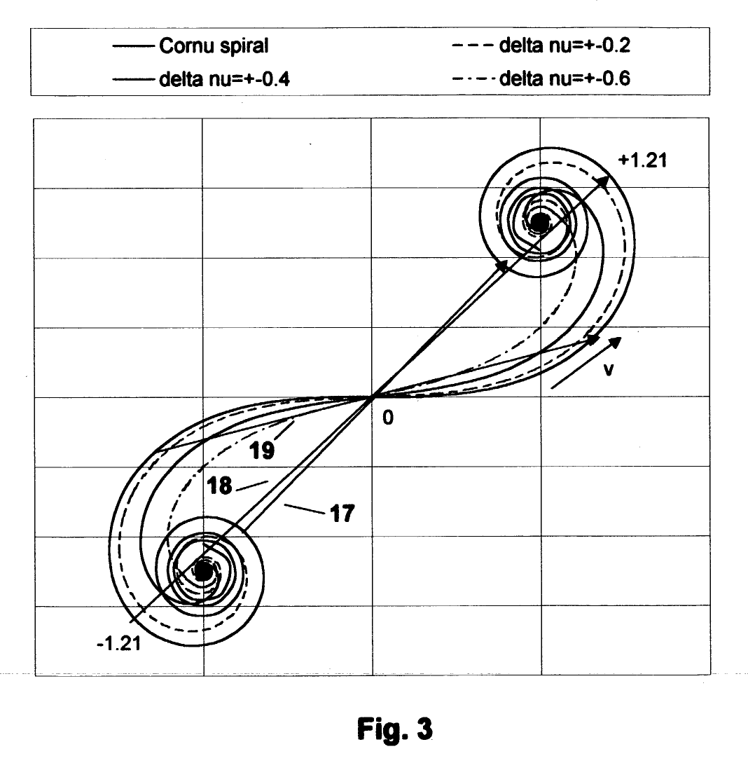

The invention is used in the context of Ultra High Resolution Lithography. FIG. 1 shows a schematic exposure system. Rays of light from a distant point source, pass through a slit and form a Fresnel pattern, or image, at a distance G behind the slit. The various rays suffer phase lags which depend individually on their distance, s, from the center line of the slit, i.e. the phase lags depend on 2πs²/λ,. A simulation of the current that is transmitted by the mask is shown in FIG. 2. The current is pinched at the “sweet spot” at a critical distance below the mask. The optical foundation for critical condition is illustrated in FIG. 3

Consider the dimensionless spatial coordinate, defined:

$$v = s \sqrt{\frac{2}{G λ}} = \sqrt{2 {\tilde{N}}_{F}} , \qquad ( 1 )$$

and the dimensionless slit width:

$$Δ v = Δ s \sqrt{\frac{2}{G λ}} ,$$

corresponding to a “demagnification” M, where

$$Δ v = M ω \sqrt{\frac{2}{G λ}} , \qquad ( 2 )$$

and where

G∝M², (3)

for given Δν and λ, while:

s is a distance measured from the axis of the slit/clear mask feature in its plane (FIG. 1)

G is the width of the mask/wafer gap (FIG. 1)

λ is the wavelength of the radiation used, and

N_{F} is the number of Fresnel half zones² across the slit/clear mask feature

νis a dimensionless spatial co-ordinate

Δs is the slit width (equal to W)

Δν is dimensionless spatial co-ordinate, or dimensionless slit width, corresponding to Δs at a given G and λ

M is the demagnification factor

ω the print feature size

The vectorial addition of the amplitudes and phases of rays passing through the slit and interfering constructively at the plane of the wafer are represented by vectors, as in FIG. 3, for the amplitude summed over all rays on axis at the wafer (FIG. 1). The amplitudes are represented mathematically with Fresnel integrals or summed graphically with Cornu's spiral, i.e. the vibration curve. The Critical Condition occurs when the width of a transmitting mask feature, Δs, is related to the mask/wafer gap G and X-ray wavelength λ by the equation:

$$\frac{Δ s}{\sqrt{λ G}} = 1.7 \qquad ( 4 )$$

so that the vector C in FIG. 1, representing the on-axis amplitude at the wafer, is maximum. Then Δν=2.42.

“Sweet Spot” (SS) definition:

The Sweet Spot occurs around CC. It appears in FIG. 2 as a narrow band of intense current that is typically used in UHRL for demagnifiying the clear mask feature.

Oscillation Condition (OC) definition:

An oscillation condition occurs upstream from CC. Oscillations occur in the Fresnel pattern. At an oscillation condition there is, typically, a minimum or maximum on the image axis. The first, one-dimensional, oscillation condition occurs where Δν=3.8 for a mask slit. This condition corresponds to the vector O in FIG. 3. Other OCs occur near mask-wafer gaps corresponding to the extremal values of Δν equal to 4.7, 5.5, 7.6 and so on. For all OCs, Δν>2.42. All OCs occur closer to the mask than the CC.

Operation—main embodiment

My method using Fresnel oscillations is employed within the context of UHRL. For a given wavelength, or range of wavelengths, and given clear mask feature size, the mask-wafer gap is set so that the Fresnel pattern at the resist contains selected oscillations. For the simplest case of a slit mask feature, the first oscillation pattern occurs when the dimensionless slit width, Δν˜3.8. A development level is chosen so that fine oscillation lines within the Fresnel pattern are printed. Typically the oscillation lines have a finer resolution than for UHRL employed near CC.

I show how to select oscillation patterns in Fresnel diffraction, whether by using single exposures or by using multiple exposures. By using the adapted Cornu spiral or by other simulations, I show how to optimise the exposures. The methods extend to the superposition of exposures and this is particularly applicable to developing fine two-dimensional patterns.

Typically, 0.8 nm (1.5 kV) X-rays are used in the illumination within the dimensionless range Δν=2.4±0.2, corresponding to a wavelength range 0.55<λ<1.1 nm and energy range 1<ε<2 kV when the CC is set, by gap and mask feature size, for the mean value. Typically a synchrotron X-ray source is used. More generally any wavelength of radiation or matter can be used in proximity printing and a different range in wavelengths may achieve optimisation in resolution and exposure time.

Typically, mask features are shaped following principles of temporal and spatial coherence as in MASC.

No lenses, mirrors or other optics are placed between the mask and wafer which are maintained, typically, in precise proximity at a calculated separation.

Typically, exposures are made to relate to a development level parametrized in a controlled development process so that a corresponding multiple bias is developed for a selected demagnification.

FIG. 1 is a schematic exposure system according to the invention including two rays of radiation, 10, typically from a distant synchrotron radiation source, passing through a slit of width Δs, in an absorbing mask, 11, and constructing an image at the axial point A, on the plane of the wafer, 12. The incident off-axis ray suffers a phase lag 15 equal to 2πs²/λ. as can be seen from the distance separating the wave-front 14 from the plane of the mask 11.

FIG. 2 represents a simulation of a Fresnel diffracted current, with wavelength λ=0.8 nm, passing through a slit of width 150 nm . The height is 40 μm. The critical condition occurs where Δν=2.42. One oscillation condition occurs near Δν˜3.8 The simulation was obtained using the SEMPER program. The intensity is shown by grey-scale and the distance below the mask is indicated through the dimensionless spatial co-ordinate at various values of ν corresponding to the vectors shown in the FIG. 3.

FIG. 3 represents the Cornu spiral (or vibration curve) utilized by the invention. The outer spiral is the Cornu spiral that applies to patterning with monochromatic radiation. For monochromatic incidence, when δν=0 as in the outermost spiral, the vector, 17, represents the amplitude of the image on axis at an Oscillation Condition when Δν=3.8. The vector is the sum over all ray phases for which mod(s)≦Δs/2, and it represents the amplitude of the aerial image on axis at the Oscillation Condition. Vector 19 at Δν=1.4, represents the amplitude of a summed rays at a point beyond CC, while the vector 18 at Δν=2.4, shows the amplitude near at the Critical Condition.

When λ is not monochromatic but is spread over a range δλ, then from equation 1 it follows that δν/ν=−δλ/2λ and the Fresnel integrals represented in FIG. 3 can be averaged. Using windows of various δν, corresponding spirals represent amplitudes and phases using three broad band illumninations: for δν=±0.2; for δν=±0.4; and for δν=±0.6. The adapted spirals show the effect of temporal coherence. δν˜0.2 is a typical value when synchrotron radiation is used as the light source. For each condition, vectors corresponding to 17, 18 and 19 can readily be drawn.

The general spiral contraction that occurs with increasing bandwidth δν implies a reduction in high frequency oscillations at large δν. The vectors demonstrate the various conditions for various types of imaging, including CC and OC. The adapted spirals are used to determine the optimum bandwidth for printing a specified feature size. The intensities displayed in the following three plots are the squares of amplitudes.

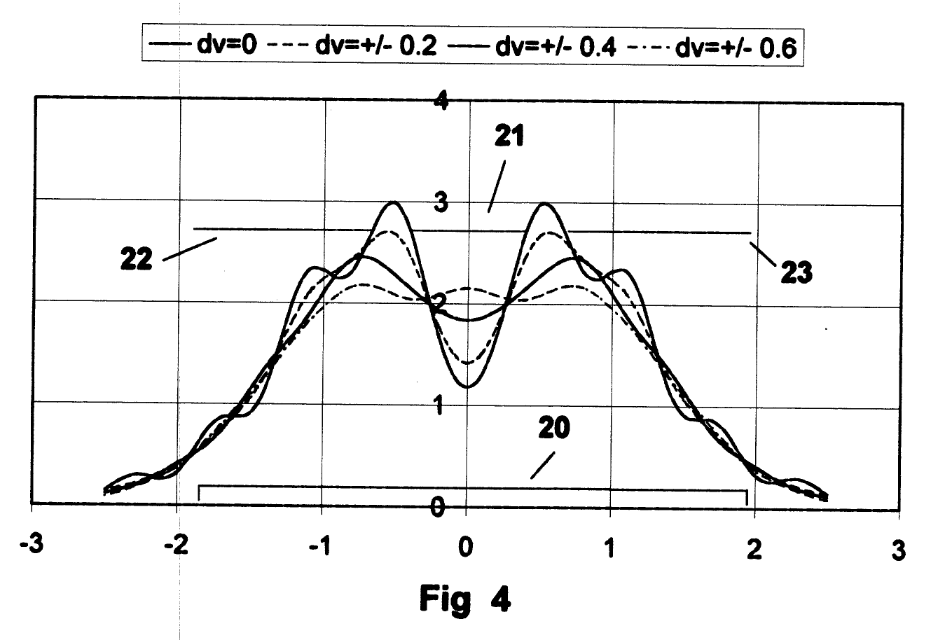

FIG. 4 represents simulated aerial images near one of the oscillation conditions, Δν=3.8, for monochromatic rays (upper curve) and for various degrees of broad-band illumination following FIG. 3. The horizontal line 20 under the curve shows the slit width. The abscissae scale is the dimensionless spatial coordinate ν and the ordinate is the intensity.

The profiles are constructed by scanning the vector Δν from its symmetrical position, on axis, to off-axis positions by amounts ν at the resist. When the combination of exposure and development level is chosen at the ordinate value 2.75, then two lines are printed with a demagnification of 17X relative to the dimensionless slit width 20 shown above the abscissae in the figure. Then item 21 is the internal bias and items 22 and 23 are a pair of one sided biases. The aerial image profiles result from two sequential integrations: firstly temporal and then spatial. The incident dose at the mask occurs at ordinate level 2 in this figure and in the following two figures.

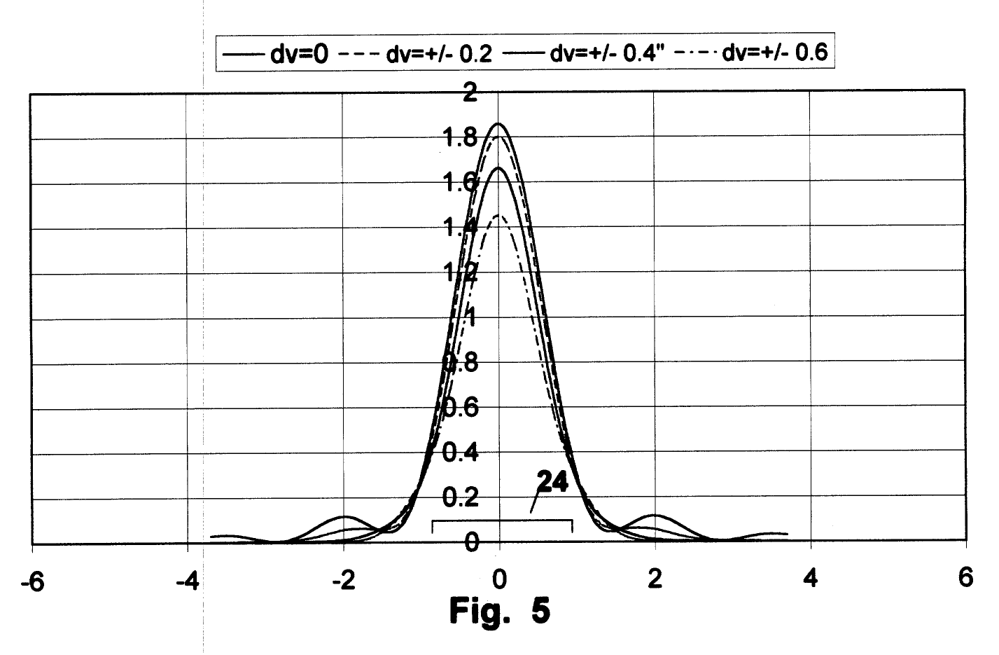

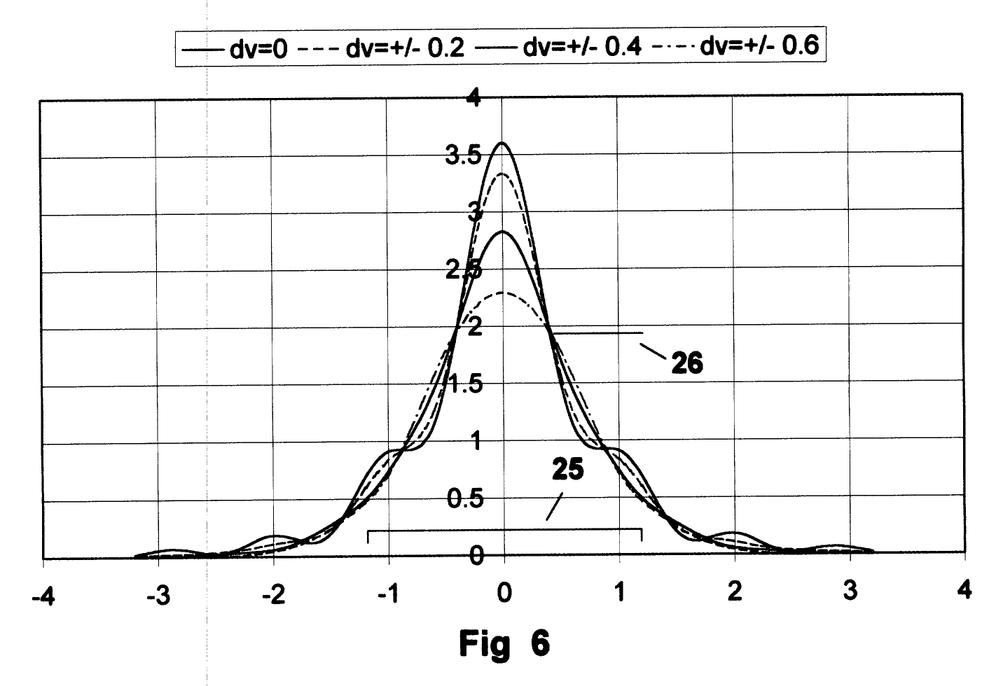

When Δν=1.3, corresponding aerial images are shown in FIG. 5 with the monochromatic pattern again on the upper curve. This figure illustrates the comparative broadening of the aerial pattern relative to the dimensionless slit width, Δν, as its value decreases. This condition had been typically used for 1X PXL and is shown, along with the following FIG. 6, to illustrate the importance of internal bias for high demagnification and resolution. Item 24 is the corresponding slit width. The scales are as for FIG. 4.

At CC, when Δν=2.42, aerial images are shown in FIG. 6, for monochromatic rays (upper curve) and for the various broad-band illuminations as before. The scales are, again, as for FIG. 4. The horizontal line 25 under the curve shows the slit width. This condition was adapted to 3X printing as in UHRL, when item 26 represents one sided bias.

FIGS. 4-6 provide a method for comparing, for various exposure systems and bandwidths, process features including internal bias, side bias, development level, line width, mask-wafer gap, demagnification factor, contrast (slope in the plots), and exposure time. The figures illustrate the comparatively large demagnification factors, up to 20X, that result from printing Fresnel Oscillations. The method makes it possible to optimise the process. The method is enhanced by further simulations including such simulations as described in MASC.

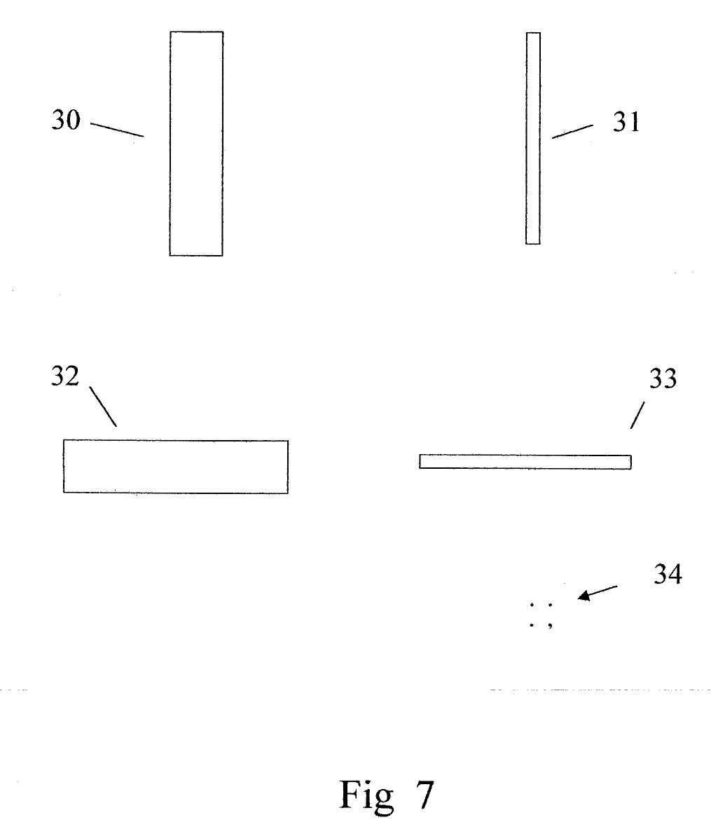

FIG. 7 shows a schematic example of a fine two-dimensional pattern, for printing after two exposures of slit type patterns. Item 30 shows a vertical slit and item 31 shows the corresponding dose above a selected level of 2.75 on FIG. 4. Item 32 shows the corresponding horizontal slit and item 32 shows the corresponding dose above the selected level. Item 33 shows the corresponding print after superposition by double exposure and a development level of 5.5, using the scale of FIG. 4 but doubled for the double exposure. The print will consist of four squares, each one sixteenth the width of the slit. Many other superpositions can be given to print other finer and more complex patterns.

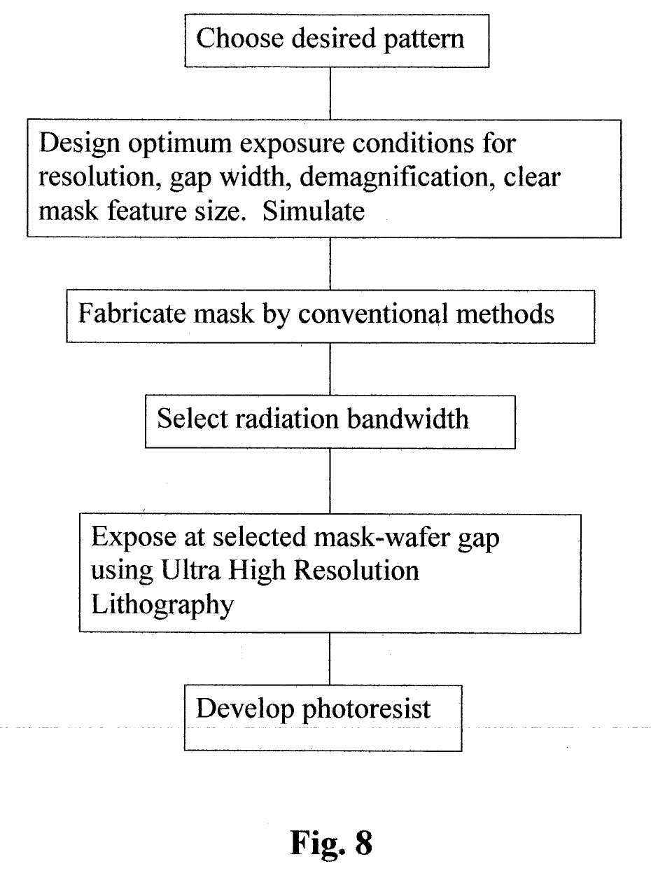

FIG. 8 is a high level flow chart showing the inventive procedure. For a specified design pattern, optimum exposure conditions are designed, including resolution, demagnification factor, mask-wafer gap, clear mask feature size. A development level is selected to print a required pattern and procedure. FIG. 4 is used to select a trade between optimum bandwidth for optimum contrast and throughput at the resist. Typically simulations are performed. The mask is fabricated by conventional methods. An optimum bandwidth of X-rays is selected. An exposure is made and the resist is developed at a selected and parametrized level.

The method of Fresnel oscillations shows how, beyond UHRL, to design and select mask-wafer gaps to print oscillation patterns near an OC The method of Fresnel oscillations applies to two-dimensional imaging through sequential superposition of oscillation effects. Moreover, the method shows how to produce fine oscillation prints in two dimensions by multiple exposures or by single exposures.

Further scope and applicability of the present method of Fresnel oscillations will become apparent from the detailed description. However, it should be understood that the detailed description and specific examples, while indicating preferred embodiments of the method of Fresnel oscillations are given by way of illustration only, since various changes and modifications within the spirit and scope of the invention will become apparent to those skilled in the art from the detailed description.

Alternative embodiments

Fine prints, obtained from oscillations in Fresnel patterns in UHRL, can be applied to proximity printing using radiation or matter, including electromagnetic, electrons, protons or ions, of whatever wavelength.

The source may be monochromatic or broad-band. If broad band, then the bandwidth is selected by a variety of means, including use of filters, reflecting mirrors, source operating parameters and simulations of exposures for printing with optimised exposure times.

The method of Fresnel oscillations being thus described, it will be obvious that the same may be varied in many ways. Such variations are not to be regarded as departure from the spirit and scope of the invention, and all such modifications as would be obvious to one skilled in the art are intended to be included within the scope of the following claims.

Conclusion, ramifications and scope

The method of Fresnel oscillations provides the means, methods and principles for optimizing the printing of fine, one-dimensional and of fine, two-dimensional patterns in UHRL. Demagnifications down to 20X are possible by the use of internal bias. The method has the advantage of ultra high resolution and simplicity. The method has experimental advantages including comparatively large sizes of mask-wafer gap. The method is available with bright sources and so has additional advantages of rapid speed and high throughput. The means, methods and principles apply to proximity printing by radiation or matter of whatever wavelength. The method is applicable to a wide range of manufacturing including advanced integrated circuits, micromachines and micro electro-mechanical systems.

I claim:

1. A method for printing fine features in ultra high resolution lithography comprising:
placing the mask relative to the resist such that a gap width is formed therebetween and such that said resist is not disposed at a real image plane relative to said mask, and an exposure source, and
using internal bias to select multiple oscillations in a Fresnel diffraction pattern, and exposing said resist with said exposure source,
whereby fine oscillation patterns are printed at selected demagnifications.

2. The method according to claim 1, said selecting step selecting the demagnifying value from a range of 3X to about 20X.

3. The method according to claim 2, said selecting step including:
calculating the exposure conditions, including dose and development level, for multiple bias, including internal bias and external bias, and calculating mask features at the selected demagnification value; and
calculating the gap width between the mask and the photoresist

4. The method according to claim 3, further comprising:
setting the gap width to the calculated gap width

5. The method according to claim 3, said multiple bias calculation step including:
assuming a development level utilized by said exposing step; and
applying Fresnel diffraction analysis using the assumed development level to calculate the multiple bias for demagnifying mask features at the demagnification value.

6. The method according to claim 3, further comprising:
said internal bias and gap width calculation steps utilizing the following equations:
b′″=2f′″(I)\sqrt{G λ/2}
$$\begin{matrix}v = s \sqrt{\frac{2}{G λ}} = \sqrt{2 {\tilde{N}}_{F}} , & ( 1 ) \\ Δ v = M ω \sqrt{\frac{2}{G λ}} , & ( 2 )\end{matrix}$$
G∝M² (3)
Where:
b′″ is the multiple bias,
s is a distance measured from the axis of the slit/clear mask feature in its plane (FIG. 1)
G is the width of the mask/wafer gap (FIG. 1)
λis the wavelength of the radiation used, and
N_{F} is the number of Fresnel half zones across the slit/clear mask feature
f′″ (I) is a function of the intensity of the aerial image. Notice that f′″ depends on the intensity selected for the development, through exposure time and resist processing, and f′″ depends also on the shape of the aerial image.
ν is a dimensionless spatial co-ordinate
Δs is the slit width (equal to W)
Δν is dimensionless spatial co-ordinate, or dimensionless slit width, corresponding to Δs at a given G and λ
M is the demagnification factor
ω the print feature size

7. The method according to claim 6, wherein the dimensionless slit width Δν is greater than 2.4 for any wavelength λ of electromagnetic waves or particles.

8. The method according to claim 7, wherein the dimensionless slit width Δν is about 3.8 for any wavelength λ of electromagnetic waves or particles.

9. The method according to claim 1, further comprising:
developing the photoresist

10. The method according to claim 1, said exposing step exposing the photoresist without lenses by passing electromagnetic waves through the mask.

11. The method according to claim 9, wherein the electromagnetic rays are X-rays with a print resolution between 10 micrometers and about 5 nanometers.

12. The method according to claim 1,
said exposing step exposing the resist by passing ions or particles through the mask.

13. The method according to claim 1,
said exposing step controlling an exposure dose by performing multiple exposures with crossed mask patterns,
whereby a combined dose may be applied to print selected fine oscillations.

15. A device produced by the method of claim 1.

16. The method according to claim 1, wherein the step of demagnifying with internal bias, the exposure source includes at least two rays, and one of the two rays undergoes a phase lag with respect to another one of the two rays upon passing through the mask.
